(19) United States
(12) Patent Application Publication
(10) Pub. No.: US 2015/0112498 A1
(43) Pub. Date: Apr. 23, 2015

(54) Methods of Patel Loadflow Computation for Electrical Power System

(71) Applicant: Sureshchandra B Patel, (US)

(72) Inventor: Sureshchandra B Patel, Toronto (CA)

(21) Appl. No.: 14/492,428

(22) Filed: Sep. 22, 2014

(30) Foreign Application Priority Data
Sep. 23, 2013 (CA) 2827701

(51) Int. Cl. G05B 17/02; G05F 1/66; G06F 17/50

(52) U.S. Cl. CPC G05B 17/02; G06F 17/5009; G05F 1/66
USPC 700/291

(57) ABSTRACT

Highly efficient and reliable methods of Current Injection Patel Super Decoupled Loadflow (CIPSDL), New Gauss-Seidel-Patel Loadflow (NGSPL), Decoupled Gaus-Seidel-Patel Loadflow, and Current Injection Newton-Raphson-Patel Loadflow (CINRPL) are invented. One of the versions CIPSDL method is characterized in 1) the use of the same coefficient matrix [−Y] for both the RI-f and II-e sub-problems, and in all the methods 2) all the nodes being active, no re-factorization of gain matrices [−Y], [Y], [Y*] are required for implementation of Q-limit violations. The invented DGSPL calculation method is characterized in decoupling the calculation of real and imaginary components of complex node voltage leading to increased stability and efficiency of the DGSPL calculation method. Also invented are Constant Matrix Patel Loadflow (CMPL) and Patel Transformation Decoupled Loadflow (PTDL) methods.

### FIELD OF THE INVENTION

The present invention relates to a method of loadflow computation in power flow control and voltage control for an electrical power system.

### BACKGROUND OF THE INVENTION

The present invention relates to power-flow/voltage control in utility/industrial power networks of the types including many power plants/generators interconnected through transmission/distribution lines to other loads and motors. Each of these components of the power network is protected against unhealthy or alternatively faulty, over/under voltage, and/or over loaded damaging operating conditions. Such a protection is automatic and operates without the consent of power network operator, and takes an unhealthy component out of service by disconnecting it from the network. The time domain of operation of the protection is of the order of milliseconds.

The purpose of a utility/industrial power network is to meet the electricity demands of its various consumers 24-hours a day, 7-days a week while maintaining the quality of electricity supply. The quality of electricity supply means the consumer demands be met at specified voltage and frequency levels without over loaded, under/over voltage operation of any of the power network components. The operation of a power network is different at different times due to changing consumer demands and development of any faulty/contingency situation. In other words healthy operating power network is constantly subjected to small and large disturbances. These disturbances could be consumer/operator initiated, or initiated by overload and under/over voltage alleviating functions collectively referred to as security control functions and various optimization functions such as economic operation and minimization of losses, or caused by a fault/contingency incident.

For example, a power network is operating healthy and meeting quality electricity needs of its consumers. A fault occurs on a line or a transformer or a generator which faulty component gets isolated from the rest of the healthy network by virtue of the automatic operation of its protection. Such a disturbance would cause a change in the pattern of power flows in the network, which can cause over loading of one or more of the other components and/or over/under voltage at one or more nodes in the rest of the network. This in turn can isolate one or more other components out of service by virtue of the operation of associated protection, which disturbance can trigger chain reaction disintegrating the power network.

Therefore, the most basic and integral part of all other functions including optimizations in power network operation and control is security control. Security control means controlling power flows so that no component of the network is over loaded and controlling voltages such that there is no over voltage or under voltage at any of the nodes in the network following a disturbance small or large. As is well known, controlling electric power flows include both controlling real power flows which is given in MWs, and controlling reactive power flows which is given in MVARs. Security control functions or alternatively overloads alleviation and over/under voltage alleviation functions can be realized through one or combination of more controls in the network. These involve control of power flow over tie line connecting other utility network, turbine steam/water/gas input control to control real power generated by each generator, load shedding function curtails load demands of consumers, excitation controls reactive power generated by individual generator which essentially controls generator terminal voltage, transformer taps control connected node voltage, switching in/out in capacitor/reactor banks controls reactive power at the connected node.

Control of an electrical power system involving power-flow control and voltage control commonly is performed according to a process shown in FIG. 5, which is a method of forming/defining a loadflow computation model of a power network to affect control of voltages and power flows in a power system comprising the steps of:
Step-10: obtaining on-line/simulated data of open/close status of all switches and circuit breakers in the power network, and reading data of operating limits of components of the power network including maximum power carrying capability limits of transmission lines, transformers, and PV-node, a generator-node where Real-Power-P and Voltage-Magnitude-V are given/assigned/specified/set, maximum and minimum reactive power generation capability limits of generators, and transformers tap position limits, or stated alternatively in a single statement as reading operating limits of components of the power network,
Step-20: obtaining on-line readings of given/assigned/specified/set Real-Power-P and Reactive-Power-Q at PQ-nodes, Real-Power-P and voltage-magnitude-V at PV-nodes, voltage magnitude and angle at a reference/slack node, and transformer turns ratios, wherein said on-line readings are the controlled variables/parameters,
Step-30: performing loadflow computation to calculate, depending on loadflow computation model used, complex voltages or their real and imaginary components or voltage magnitude corrections and voltage angle corrections at nodes of the power network providing for calculation of power flow through different components of the power network, and to calculate reactive power generation and transformer tap-position indications,
Step-40: evaluating the results of Loadflow computation of step-30 for any over loaded power network components like transmission lines and transformers, and over/under voltages at different nodes in the power system,
Step-50: if the system state is acceptable implying no over loaded transmission lines and transformers and no over/under voltages, the process branches to step-70, and if otherwise, then to step-60,
Step-60: correcting one or more controlled variables/parameters set in step-20 or at later set by the previous process cycle step-60 and returns to step-30,
Step-70: affecting a change in power flow through components of the power network and voltage magnitudes and angles at the nodes of the power network by actually implementing the finally obtained values of controlled variables/parameters after evaluating step finds a good power system or stated alternatively as the power network without any overloaded components and under/over voltages, which finally obtained controlled variables/parameters however are stored for acting upon fast in case a simulated event actually occurs or stated alternatively as actually implementing the corrected controlled variables/parameters to obtain secure/correct/acceptable operation of power system.

Overload and under/over voltage alleviation functions produce changes in controlled variables/parameters in step-60 of FIG. 5. In other words controlled variables/parameters are assigned or changed to the new values in step-60. This correction in controlled variables/parameters could be even optimized in case of simulation of all possible imaginable disturbances including outage of a line and loss of generation for corrective action stored and made readily available for acting upon in case the simulated disturbance actually occurs in the power network. In fact simulation of all possible imaginable disturbances is the modern practice because corrective actions need be taken before the operation of individual protection of the power network components.

It is obvious that loadflow computation consequently is performed many times in real-time operation and control environment and, therefore, efficient and high-speed loadflow computation is necessary to provide corrective control in the changing power system conditions including an outage or failure of any of the power network components. Moreover, the loadflow computation must be highly reliable to yield converged solution under a wide range of system operating conditions and network parameters. Failure to yield converged loadflow solution creates blind spot as to what exactly could be happening in the network leading to potentially damaging operational and control decisions/actions in capital-intensive power utilities.

The power system control process shown in FIG. 5 is very general and elaborate. It includes control of power-flows through network components and voltage control at network nodes. However, the control of voltage magnitude at connected nodes within reactive power generation capabilities of electrical machines including generators, synchronous motors, and capacitor/inductor banks, and within operating ranges of transformer taps is normally integral part of loadflow computation as described in “LTC Transformers and MVAR violations in the Fast Decoupled Load Flow, IEEE Trans., PAS-101, No. 9, PP. 3328-3332, September 1982.” If under/over voltage still exists in the results of loadflow computation, other control actions, manual or automatic, may be taken in step-60 in the above and in FIG. 5. For example, under voltage can be alleviated by shedding some of the load connected.

The prior art and present invention are described using the following symbols and terms:
Y̅_{pq}=G_{pq}+jB_{pq}: (p−q) th element of nodal admittance matrix without shunts
Yₚₚ=Gₚₚ+jBₚₚ: p-th diagonal element of nodal admittance matrix without shunts
yₚ=gₚ+jbₚ: total shunt admittance at any node-p
Vₚ=eₚ+jfₚ=Vₚ∠θₚ: complex voltage of any node-p
Y_{pq}=G_{pq}+jB_{pq}: (p−q) th element of nodal admittance matrix without shunts
Yₚₚ=Gₚₚ+jBₚₚ: p-th diagonal element of nodal admittance matrix without shunts
yₚ=gₚ+jbₚ: total shunt admittance at any node-p
Vₚ=eₚ+jfₚ=Vₚ∠θₚ: complex voltage of any node-p
Vₛ=eₛ+jfₛ=Vₛ∠θₛ: complex slack-node voltage
Δθₚ, ΔVₚ: voltage angle, magnitude corrections
Δfₚ, Δeₚ: imaginary, real part of complex voltage corrections
Pₚ+jQₚ: net nodal injected power, calculated
ΔPₚ+jΔQₚ: nodal power residue or mismatch
RPₚ+jRQₚ: modified nodal power residue or mismatch
RIₚ+jIIₚ: net nodal injected current, calculated
ΔRIₚ+jΔIIₚ: nodal current residue or mismatch
RRIₚ+jRIIₚ: modified nodal current residue or mismatch
PSHₚ+jQSHₚ: net nodal injected power, scheduled/specified
Cₚ=1∠Φₚ=Cos Φₚ+j Sin Φₚ: Unitary rotation/transformation
m: number of PQ-nodes
k: number of PV-nodes
n=m+k+1: total number of nodes
q>p: node-q is connected to node-p excluding the case of q=p
[ ]: indicates enclosed variable symbol to be a vector or matrix
LRA: Limiting Rotation Angle, −36° for prior art, −48° for invented models
PQ-node: load-node, where, Real-Power-P and Reactive-Power-Q are specified
PV-node: generator-node, where, Real-Power-P and Voltage-Magnitude-V are specified
Loadflow Computation: Each node in a power network is associated with four electrical quantities, which are voltage magnitude, voltage angle, real power, and reactive power. The loadflow computation involves calculation/determination of two unknown electrical quantities for other two given/specified/scheduled/set/known electrical quantities for each node. In other words the loadflow computation involves determination of unknown quantities in dependence on the given/specified/scheduled/set/known electrical quantities.
Loadflow Model: a set of equations describing the physical power network and its operation for the purpose of loadflow computation. The term loadflow model′ can be alternatively referred to as ‘model of the power network for loadflow computation’. The process of writing Mathematical equations that describe physical power network and its operation is called Mathematical Modeling. If the equations do not describe/represent the power network and its operation accurately the model is inaccurate, and the iterative loadflow computation method could be slow and unreliable in yielding converged loadflow computation. There could be variety of Loadflow Models depending on organization of set of equations describing the physical power network and its operation, including Decoupled Loadflow Models, Super Decoupled Loadflow Models, Fast Super Decoupled Loadflow (FSDL) Model, and Super Super Decoupled Loadflow (SSDL) Model.
Loadflow Method: sequence of steps used to solve a set of equations describing the physical power network and its operation for the purpose of loadflow computation is called Loadflow Method, which term can alternatively be referred to as loadflow computation method′ or ‘method of loadflow computation’. One word for a set of equations describing the physical power network and its operation is: Model. In other words, sequence of steps used to solve a Loadflow Model is a Loadflow Method. The loadflow method involves definition/formation of a loadflow model and its solution. There could be variety of Loadflow Methods depending on a loadflow model and iterative scheme used to solve the model including Decoupled Loadflow Methods, Super Decoupled Loadflow Methods, Fast Super Decoupled Loadflow (FSDL) Method, and Super Super Decoupled Loadflow (SSDL) Method. All decoupled loadflow methods described in this application use either successive (1θ, 1V) iteration scheme or simultaneous (1V, 1θ) iteration scheme, defined in the following.

Prior art method of loadflow computation of the kind carried out as step-30 in FIG. 5, include a class of methods known as decoupled loadflow. This class of methods consists of decoupled loadflow and super decoupled loadflow methods including Super Super Decoupled Loadflow method all formulated involving Power Mismatch computation and polar coordinates. Prior-art Loadflow Computation Methods are described in details in the following documents of Research publications and granted patents. Therefore, prior art methods will not be described here.

### Major Research Publications

1) “Super Super Decoupled Loadflow” Presented at IEEE Toronto International Conference—Science and Technology for Humanity (TIC-STH 2009), pp. 652-659, 26-27 Sep., 2009
2) “Fast Super Decoupled Loadflow” IEE Proceedings Part-C, Vol. 139, No. 1, pp. 13-20, January 1992

### Patents

1. “Method of Fast Super Decoupled Loadflow Computation for Electrical Power System”, Canadian Patent #2107388 issued Jul. 5, 2011
2. “Method of Super Super Decoupled Loadflow Computation for Electrical Power System”, Canadian Patent #2548096 issued Jan. 5, 2011
3. “Method and Apparatus for Parallel Loadflow Computation for Electrical Power System”, Canadian Patent #2564625 issued Mar. 9, 2011
4. “Method of Loadflow Computation for Electrical Power System”, Canadian Patent #2661753 issued Oct. 11, 2011

### SUMMARY OF THE INVENTION

It is a primary object of the present invention to improve convergence and efficiency of the prior art Super Super Decoupled Loadflow computation method under wide range of system operating conditions and network parameters for use in power flow control and voltage control in the power system. A further object of the invention is to reduce computer storage/memory or calculating volume requirements.

The above and other objects are achieved, according to the present invention, with one of the Current Injection Patel Super Decoupled Loadflow, YY-version (CIPSDL-YY), XX-version (CIPSDL-XX), New Gauss-Seidel-Patel Loadflow (NGSPL), Decoupled Gauss-Seidel-Patel Loadflow (DGSPL), Complex Newton-Raphson-Patel Loadflow (CNRPL), Constant Matrix Patel Loadflow (CMPL), Patel Transformation Decoupled Loadflow (PTDL) Methods and their many variants, for loadflow calculation for Electrical Power System. In context of voltage control, one of the inventive system of CIPSDL and others listed in the above methods of loadflow computation for Electrical Power system consisting of plurality of electromechanical rotating machines, transformers and electrical loads connected in a network, each machine having a reactive power characteristic and an excitation element which is controllable for adjusting the reactive power generated or absorbed by the machine, and some of the transformers each having a tap changing element, which is controllable for adjusting turns ratio or alternatively terminal voltage of the transformer, said system comprising:
means defining and solving loadflow model of the power network characterized by inventive CIPSDL and other listed in the above methods of loadflow computation models for providing an indication of the quantity of reactive power to be supplied by each generator including the reference/slack node generator, and for providing an indication of turns ratio of each tap-changing transformer in dependence on the obtained-online or given/specified/set/known controlled network variables/parameters, and physical limits of operation of the network components,
machine control means connected to the said means defining and solving loadflow model and to the excitation elements of the rotating machines for controlling the operation of the excitation elements of machines to produce or absorb the amount of reactive power indicated by said means defining and solving loadflow model in dependence on the set of obtained-online or given/specified/set controlled network variables/parameters, and physical limits of excitation elements,
transformer tap position control means connected to the said means defining and solving loadflow model and to the tap changing elements of the controllable transformers for controlling the operation of the tap changing elements to adjust the turns ratios of transformers indicated by the said means defining and solving loadflow model in dependence on the set of obtained-online or given/specified/set controlled network variables/parameters, and operating limits of the tap-changing elements.

The method and system of voltage control according to the preferred embodiment of the present invention provide voltage control for the nodes connected to PV-node generators and tap changing transformers for a network in which real power assignments have already been fixed. The said voltage control is realized by controlling reactive power generation and transformer tap positions.

One of the inventive system of Current Injection Patel Super Decoupled Loadflow (CIPSDL) or other listed in the above Loadflow methods of computation can be used to solve a model of the Electrical Power System for voltage control. For this purpose real and reactive power assignments or settings at PQ-nodes, real power and voltage magnitude assignments or settings at PV-nodes and transformer turns ratios, open/close status of all circuit breaker, the reactive capability characteristic or curve for each machine, maximum and minimum tap positions limits of tap changing transformers, operating limits of all other network components, and the impedance or admittance of all lines are supplied. A decoupled loadflow system of equations (1) and (2) is solved by an iterative process until convergence. During this solution the quantities which can vary are the real and reactive power at the reference/slack node, the reactive power set points for each PV-node generator, the transformer transformation ratios, and voltages on all PQ-nodes nodes, all being held within the specified ranges. When the iterative process converges to a solution, indications of reactive power generation at PV-nodes and transformer turns-ratios or tap-settings are provided. Based on the known reactive power capability characteristics of each PV-node generator, the determined reactive power values are used to adjust the excitation current to each generator to establish the reactive power set points. The transformer taps are set in accordance with the turns ratio indication provided by the system of loadflow computation.

For voltage control, system of CIPSDL or others listed in the above Methods of Loadflow computation can be employed either on-line or off-line. In off-line operation, the user can simulate and experiment with various sets of operating conditions and determine reactive power generation and transformer tap settings requirements. A general-purpose computer can implement the entire system. For on-line operation, the loadflow computation system is provided with data identifying the current real and reactive power assignments and transformer transformation ratios, the present status of all switches and circuit breakers in the network and machine characteristic curves in steps-10 and -20 in FIG. 5, and steps 12, 20, 32, 44, and 50 in FIG. 6 described below. Based on this information, a model of the system based on gain matrices of invented loadflow computation systems provide the values for the corresponding node voltages, reactive power set points for each machine and the transformation ratio and tap changer position for each transformer.

The present inventive system of loadflow computation for Electrical Power System consists of, one of the Current Injection Patel Super Decoupled Loadflow: YY-version (CIPSDL-YY) or CIPSDL-XX, or others listed in the above Methods characterized in that 1) it is possible to have single decoupled coefficient matrix solution requiring only 50% of memory used by prior art methods, 2) the presence of transformed values of known/given/specified/scheduled/set quantities in the diagonal elements of the gain matrices [Yf] and [Ye] of the decoupled loadflow sub-problem, and 3) transformation angles are restricted to maximum of −36° to −90° to be determined experimentally, 4) PV-nodes being active in both RI-f and II-e sub-problems, PQ-node to PV-node and PV-node to PQ-node switching is simple to implement, and these inventive loadflow computation steps together yield some processing acceleration and consequent efficiency gains, and are each individually inventive, and 5) modified real current mismatches at PV-nodes are determined as RRIₚ=(eₚΔPₚ)/[Kₚ(eₚ²+fₚ²)] and RIIₚ=(−fₚΔPₚ)/[Kₚ(eₚ²+fₚ²)] in order to keep gain matrices [Yf] and [Ye] symmetrical. If the value of factor Kₚ=1, the gain matrices [Yf] and [Ye] becomes unsymmetrical in that elements in the rows corresponding to PV-nodes are defined without transformation or rotation applied, as Yf_{pq}=Ye_{pq}=−B_{pq}. It is possible that Current Injection Patel Super Decoupled methods can be formulated in polar coordinates by simply replacing correction vectors [Δf] and [Δe] in equations (1) and (2) and subsequently followed equations by correction vectors [Δθ] and [ΔV]. However, it will not be easy to have single gain matrix model, because [ΔV] for PV-nodes is zero and absent.

### BRIEF DESCRIPTION OF DRAWINGS

FIG. 1 is a flow-chart of invented Current Injection Patel Super Decoupled Loadflow (CIPSDL) method

FIG. 2 is a flow-chart embodiment of the invented New Gauss-Seidel-Patel Loadflow (NGSPL) computation method

FIG. 3a and FIG. 3b are a flow-chart embodiment of the invented Decoupled Gauss-Seidel-Patel Loadflow (DGSPL) computation method

FIG. 4 is a flow-chart embodiment of the invented method of Complex Newton-Raphson-Patel Loadflow (CNRPL) using complex algebra

FIG. 5 is a flow-chart of the overall controlling method for an electrical power system involving loadflow computation as a step which can be executed using one of the loadflow computation methods embodied in FIG. 1, 2, 3 or 4

FIG. 6 is a flow-chart of the simple special case of voltage control system in overall controlling system of FIG. 5 for an electrical power system

FIG. 7 is a one-line diagram of an exemplary 6-node power network having a reference/slack/swing node, two PV-nodes, and three PQ-nodes

### DESCRIPTION OF A PREFERRED EMBODIMENT

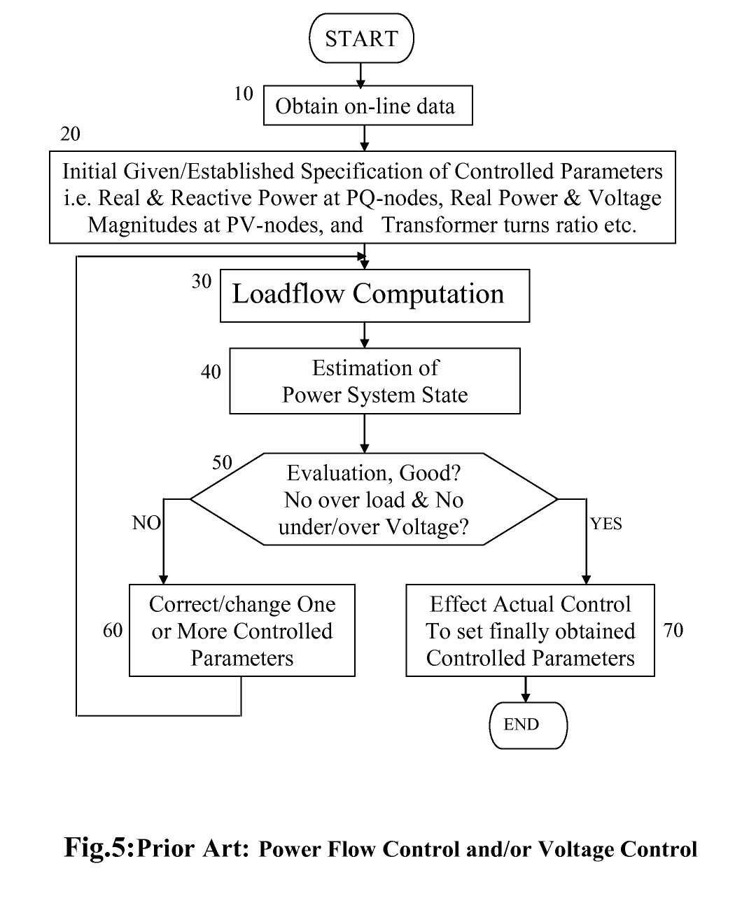

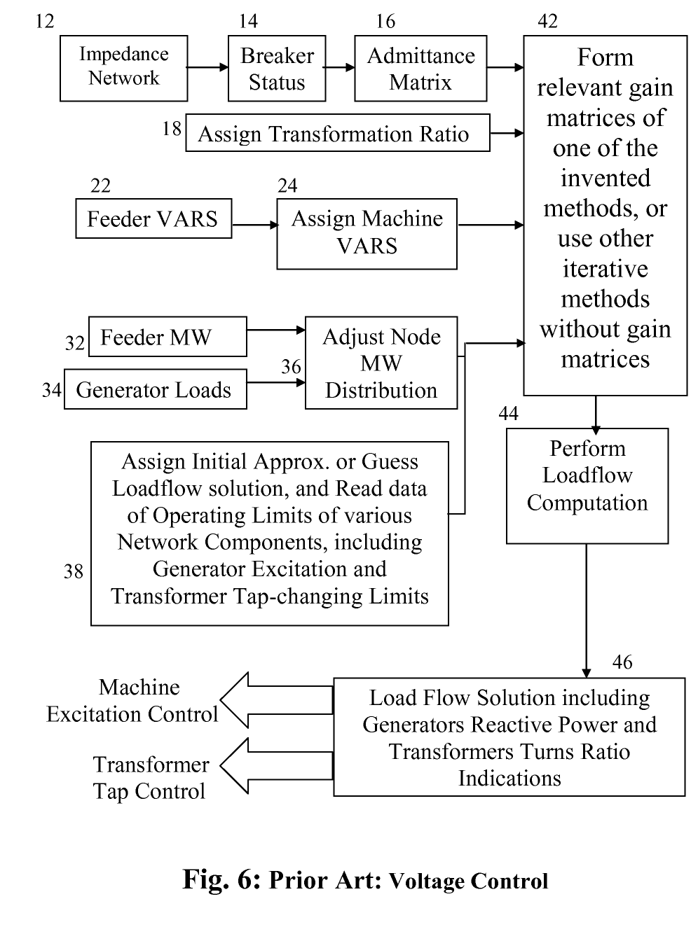

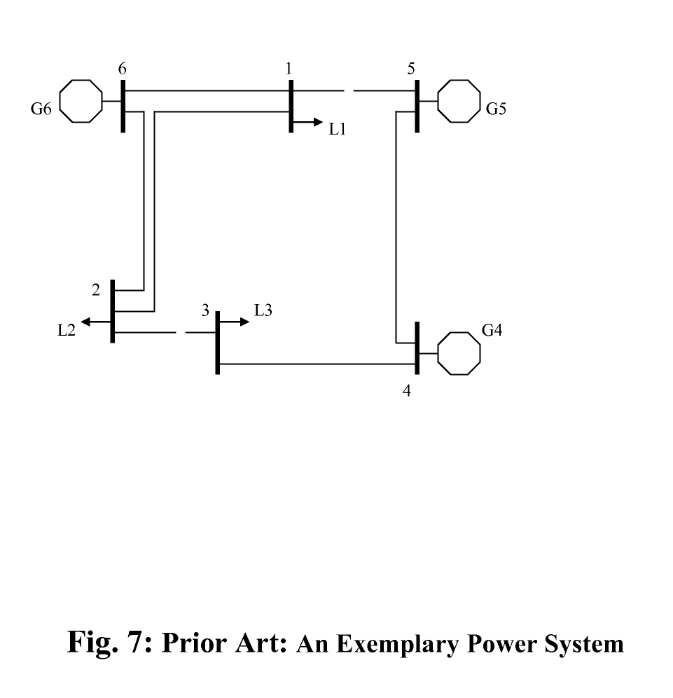

A loadflow computation is involved as a step in power flow control and/or voltage control in accordance with FIG. 5 or FIG. 6. A preferred embodiment of the present invention is described with reference to FIG. 7 as directed to achieving voltage control.

FIG. 7 is a simplified one-line diagram of an exemplary utility power network to which the present invention may be applied. The fundamentals of one-line diagrams are described in section 6.11 of the text ELEMENTS OF POWER SYSTEM ANALYSIS, forth edition, by William D. Stevenson, Jr., McGrow-Hill Company, 1982. In FIG. 7, each thick vertical line is a network node. The nodes are interconnected in a desired manner by transmission lines and transformers each having its impedance, which appears in the loadflow models. Two transformers in FIG. 7 are equipped with tap changers to control their turns ratios in order to control terminal voltage of node-1 and node-2 where large loads are connected.

Node-6 is a reference/slack-node alternatively referred to as the slack or swing-node, representing the biggest power plant in a power network. Nodes-4 and -5 are PV-nodes where generators are connected, and nodes-1, -2, and -3 are PQ-nodes where loads are connected. It should be noted that the nodes-4, -5, and -6 each represents a power plant that contains many generators in parallel operation. The single generator symbol at each of the nodes-4, -5, and -6 is equivalent of all generators in each plant. The power network further includes controllable circuit breakers located at each end of the transmission lines and transformers, and depicted by cross markings in one-line diagram of FIG. 7. The circuit breakers can be operated or in other words opened or closed manually by the power system operator or relevant circuit breakers operate automatically consequent of unhealthy or faulty operating conditions. The operation of one or more circuit breakers modify the configuration of the network. The arrows extending certain nodes represent loads.

A goal of the present invention is to provide a reliable and computationally efficient loadflow computation that appears as a step in power flow control and/or voltage control systems of FIG. 5 and FIG. 6. However, the preferred embodiment of loadflow computation as a step in control of terminal node voltages of PV-node generators and tap-changing transformers is illustrated in the flow diagram of FIG. 6 in which present invention resides in function steps 42 and 44.

Short description of other possible embodiment of the present invention is also provided herein. The present invention relates to control of utility/industrial power networks of the types including plurality of power plants/generators and one or more motors/loads, and connected to other external utility. In the utility/industrial systems of this type, it is the usual practice to adjust the real and reactive power produced by each generator and each of the other sources including synchronous condensers and capacitor/inductor banks, in order to optimize the real and reactive power generation assignments of the system. Healthy or secure operation of the network can be shifted to optimized operation through corrective control produced by optimization functions without violation of security constraints. This is referred to as security constrained optimization of operation. Such an optimization is described in the U.S. Pat. No. 5,081,591 dated Jan. 13, 1992: “Optimizing Reactive Power Distribution in an Industrial Power Network”, where the present invention can be embodied by replacing the step nos. 56 and 66 each by a step of constant gain matrices [Yf] and [Ye], and replacing steps of “Exercise Newton-Raphson Algorithm” by steps of “Exercise CIPSDL or NGSPL or DGSPL or CNRPL Computation” in places of steps 58 and 68. This is just to indicate the possible embodiment of the present invention in optimization functions like in many others including state estimation function. However, invention is being claimed through a simplified embodiment without optimization function as in FIG. 6 in this application. The inventive steps-42 and -44 in FIG. 6 are different than those corresponding steps-56, and -58, which constitute a well known Newton-Raphson loadflow method, and were not inventive even in U.S. Pat. No. 5,081,591.

In FIG. 6, function step 12 provides stored impedance values of each network component in the system. This data is modified in a function step 14, which contains stored information about the open or close status of each circuit breaker. For each breaker that is open, the function step 14 assigns very high impedance to the associated line or transformer. The resulting data is than employed in a function step 16 to establish an admittance matrix for the power network. The data provided by function step 12 can be input by the computer operator from calculations based on measured values of impedance of each line and transformer, or on the basis of impedance measurements after the power network has been assembled.

Each of the transformers T1 and T2 in FIG. 7 is a tap changing transformer having a plurality of tap positions each representing a given transformation ratio. An indication of initially assigned transformation ratio for each transformer is provided by function step 18 in FIG. 6.

The indications provided by function steps 14, and 22 are supplied to a function step 42 in which constant gain matrices [Yf] and [Ye], or [Y] or [Y*] of any of the invented CIPSDL or CNRPL models are constructed, factorized and stored. The gain matrices [Yf] and [Ye], or [Y] or [Y*] are conventional tools employed for solving CIPSDL or CNRPL models defined by equations (1) and (2), or (73) or (77) of a power system.

Indications of initial reactive power, or Q on each node, based on initial calculations or measurements, are provided by a function step 22 and these indications are used in function step 24, to assign a Q level to each generator and motor. Initially, the Q assigned to each machine can be the same as the indicated Q value for the node to which that machine is connected.

An indication of measured real power, P, on each node is supplied by function step 32. Indications of assigned/specified/scheduled/set generating plant loads that are constituted by known program are provided by function step 34, which assigns the real power, P, load for each generating plant on the basis of the total P, which must be generated within the power system. The value of P assigned to each power plant represents an economic optimum, and these values represent fixed constraints on the variations, which can be made by the system according to the present invention. The indications provided by function steps 32 and 34 are supplied to function step 36 which adjusts the P distribution on the various plant nodes accordingly. Function step 38 assigns initial approximate or guess solution to begin iterative method of loadflow computation, and reads data file of operating limits on power network components, such as maximum and minimum reactive power generation capability limits of PV-nodes generators.

The indications provided by function steps 24 36, 38 and 42 are supplied to function step 44 where inventive CIPSDL computation or NGSPL or DGSPL or CNRPL computation is carried out, the results of which appear in function step 46. The loadflow computation yields voltage magnitudes and voltage angles at PQ-nodes, real and reactive power generation by the reference/slack/swing node generator, voltage angles and reactive power generation indications at PV-nodes, and transformer turns ratio or tap position indications for tap changing transformers. The system stores in step 44 a representation of the reactive capability characteristic of each PV-node generator and these characteristics act as constraints on the reactive power that can be calculated for each PV-node generator for indication in step 46. The indications provided in step 46 actuate machine excitation control and transformer tap position control. All the loadflow computation methods using inventive CIPSDL or NGSPL or DGSPL or CNRPL computation models can be used to effect efficient and reliable voltage control in power systems as in the process flow diagram of FIG. 6.

Particularly inventive CIPSDL models in terms of equations for determining elements of vectors [RRI], [RII], and elements of gain matrices [Yf], and [Ye] of equations (1) and (2) are described followed by computation steps of the CIPSDL methods are described. The same is repeated for all other inventive models and methods.

The presence of transformed values of known/given/specified/scheduled/set quantities in the diagonal elements of the gain matrix [Yf] and [Ye] of equations (1) and (2), which takes different form for different methods, is brought about by such formulation of loadflow equations. The said transformed quantities in the diagonal elements in the gain matrices improved convergence and the reliability of obtaining converged loadflow computation

The slack-start is to use the same voltage magnitude and angle as those of the reference/slack/swing node as the initial guess solution estimate for initiating the iterative loadflow computation. With the specified/scheduled/set voltage magnitudes, PV-node voltage magnitudes are adjusted to their known values after the first P-0 iteration. This slack-start saves almost all effort of mismatch calculation in the first P-f iteration. It requires only shunt flows from each node to ground to be calculated at each node, because no flows occurs from one node to another because they are at the same voltage magnitude and angle.

### Current Injection Decoupled Loadflow Methods

In a class of decoupled loadflow models, each decoupled loadflow model comprises a system of equations (1) and (2) differing in the definition of elements of [RRI], [RII], and [Yf] and [Ye]. It is a system of equations for the separate calculation of imaginary part of and real part of complex voltage corrections.

[RRI]=[Yf][Δf] (1)

[RII]=[Ye][Δe] (2)

### Successive (1f, 1e) Iteration Scheme

In this scheme (1) and (2) are solved alternately with intermediate updating. Each iteration involves one calculation of [RRI] and [Δf] to update [f] and then one calculation of [RII] and [Δe] to update [e]. The sequence of relations (3) to (6) depicts the scheme.

[Δf]=[Yf]⁻¹[RRI] (3)

[f]=[f]+[Δf] (4)

[Δe]=[Ye]⁻¹[RII] (5)

[e]=[e]+[Δe] (6)

Where,

RRIₚ=ΔRIₚ=(eₚΔPₚ+fₚΔQₚ)/(eₚ²+fₚ²)—for PQ-nodes (7)

RIIₚ=ΔIIₚ=(eₚΔQₚ−fₚΔPₚ)/(eₚ²+fₚ²)—for PQ-nodes (8)

RRIₚ=(eₚΔPₚ)/(eₚ²+fₚ²)—for PV-nodes (9)

RIIₚ=(−fₚΔPₚ)/(eₚ²+fₚ²)—for PV-nodes (10)

The scheme involves solution of system of equations (1) and (2) in an iterative manner depicted in the sequence of relations (3) to (6). This scheme requires mismatch calculation for each half iteration because [RRI] and [RII] is calculated always using the most recent imaginary part of and real part of complex voltage values, and it is block Gauss-Seidel approach. The scheme is block successive, which imparts increased stability to the solution process, and it in turn improves convergence and increases the reliability of obtaining solution.

### Current Injection Patel Super Decoupled Loadflow: Version: CIPSDL-YY

The model comprises equations (3) to (6), and (11) to (29).

$$\begin{matrix} {RRI}_{p} = Δ {RI}_{p}^{′} = ( {e}_{p} Δ {P}_{p}^{′} + {f}_{p} Δ {Q}_{p}^{′} ) \text{/} ( {e}_{p}^{2} + {f}_{p}^{2} ) \text{-} for PQ \text{-} nodes & ( 11 ) \\ {RII}_{p} = Δ {II}_{p}^{′} = ( {e}_{p} Δ {Q}_{p}^{′} - {f}_{p} Δ {P}_{p}^{′} ) \text{/} ( {e}_{p}^{2} + {f}_{p}^{2} ) \text{-} for PQ \text{-} nodes & ( 12 ) \\ {RRI}_{p} = ( {e}_{p} Δ {P}_{p} ) \text{/} [ {K}_{p} ( {e}_{p}^{2} + {f}_{p}^{2} ) ] \text{-} for PV \text{-} nodes & ( 13 ) \\ {RII}_{p} = ( - {f}_{p} Δ {P}_{p} ) \text{/} [ {K}_{p} ( {e}_{p}^{2} + {f}_{p}^{2} ) ] \text{-} for PV \text{-} nodes & ( 14 ) \\ {Yf}_{pq} = [ \begin{matrix} - {Y}_{pq} \text{:} & for branch r \text{/} x ratio \leq 3.0 \\ - ( {B}_{pq} + 0.9 ( {Y}_{pq} - {B}_{pq} ) ) \text{:} & for branch r \text{/} x ratio > 3.0 \\ - {B}_{pq} \text{:} & \begin{matrix}for branches connected between \\ two PV \text{-} nodes or a \\ PV \text{-} node and the slack \text{-} node\end{matrix}\end{matrix} & ( 15 ) \\ {Ye}_{pq} = {Yf}_{pq} & ( 16 ) \\ {Yf}_{pp} = {bf}_{p}^{′} + {\sum }_{q > p} - {Yf}_{pq} and {Ye}_{pp} = {be}_{p}^{′} + {\sum }_{q > p} - {Ye}_{pq} & ( 17 )\end{matrix}$$

### Where,

bfₚ′=beₚ′=bₚ Cos Φₚ: for single matrix solution (18)

bfₚ′=−(QSHₚ Cos Φₚ−PSHₚ Sin Φₚ)/Vₛ²−bₚ Cos Φₚ: at PQ-node for two matrix solution (19)

beₚ′=(QSHₚ Cos Φₚ−PSHₚ Sin Φₚ)/Vₛ²−bₚ Cos Φₚ: at PQ-node for two matrix solution (20)

bfₚ′=−Qₚ₀/Vₛ²−bₚ: at PV-node for two matrix solution (21)

beₚ′=Qₚ₀/Vₛ²−bₚ: at PV-node for two matrix solution (22)

(Qₚ₀—calculated at initial estimate solution)

ΔRIₚ′=ΔRIₚ Cos Φₚ+ΔIIₚ Sin Φₚ: for PQ-nodes (23)

ΔIIₚ′=ΔIIₚ Cos Φₚ−ΔRIₚ Sin Φₚ: for PQ-nodes (24)

ΔPₚ′=ΔPₚ Cos Φₚ+ΔQₚ Sin Φₚ: for PQ-nodes (25)

ΔQₚ′=ΔQₚ Cos Φₚ−ΔPₚ Sin Φₚ: for PQ-nodes (26)

Cos Φₚ=|[Bₚₚ/√(Gₚₚ²+Bₚₚ²)]|>Cos(0° to −90°: to be determined experimentally (27)

Sin Φₚ=−|[Gₚₚ/√(Gₚₚ²+Bₚₚ²)]|≧Sin(0° to −90°: to be determined experimentally (28)

Kₚ=|(Bₚₚ/Yfₚₚ)| (29)

Branch admittance magnitude in (15) is of the same algebraic sign as its susceptance. The model consists of (3) to (6), and (11) to (29) with rotation angles to be determined experimentally and could be restricted to the maximum anywhere −36 to −90 degrees in (27) and (28). In case of systems of only PQ-nodes and without any PV-nodes, equations (22) and (23) simply be taken as Yθ_{pq}=YV_{pq}=−Y_{pq}.

### Current Injection Patel Super Decoupled Loadflow: Version: CIPSDL-XX

The CIPSDL-XX model comprises (3) to (6), (30) to (49).

$$\begin{matrix} {RRI}_{p} = Δ {RI}_{p}^{′} = ( {e}_{p} Δ {P}_{p}^{′} + {f}_{p} Δ {Q}_{p}^{′} ) \text{/} ( {e}_{p}^{2} + {f}_{p}^{2} ) \text{-} for PQ \text{-} nodes & ( 30 ) \\ {RII}_{p} = Δ {II}_{p}^{′} = ( {e}_{p} Δ {Q}_{p}^{′} - {f}_{p} Δ {P}_{p}^{′} ) \text{/} ( {e}_{p}^{2} + {f}_{p}^{2} ) \text{-} for PQ \text{-} nodes & ( 31 ) \\ {RRI}_{p} = ( {e}_{p} Δ {P}_{p} ) \text{/} [ {Kff}_{p} ( {e}_{p}^{2} + {f}_{p}^{2} ) ] \text{-} for PV \text{-} nodes & ( 32 ) \\ {RII}_{p} = ( - {f}_{p} Δ {P}_{p} ) \text{/} [ {Kee}_{p} ( {e}_{p}^{2} + {f}_{p}^{2} ) ] \text{-} for PV \text{-} nodes & ( 33 ) \\ {Yf}_{pq} = [ \begin{matrix} - [ {B}_{pq} - ( {Kf}_{p} {G}_{pp} / {B}_{pp} ) {G}_{pq} ] \text{:} & for all other branches \\ - {B}_{pq} \text{:} & \begin{matrix}\begin{matrix}for branches connected \\ between two PV \text{-} nodes\end{matrix} \\ \begin{matrix}or a PV \text{-} node and \\ the slack node\end{matrix}\end{matrix}\end{matrix} & ( 34 ) \\ {Ye}_{pq} = [ \begin{matrix} - [ {B}_{pq} - ( {Ke}_{p} {G}_{pp} / {B}_{pp} ) {G}_{pq} ] : & for all other branches \\ - {B}_{pq} : & \begin{matrix}\begin{matrix}for branches connected \\ between two PV \text{-} nodes\end{matrix} \\ \begin{matrix}or a PV \text{-} node and \\ the slack \text{-} node\end{matrix} \end{matrix}\end{matrix} & ( 35 ) \\ {Yf}_{pp} = {bf}_{p}^{′} + {\sum }_{q > p} - {Yf}_{pq} and {Ye}_{pp} = {be}_{p}^{′} + {\sum }_{q > p} - {Ye}_{pq} & ( 36 )\end{matrix}$$

### Where,

bfₚ′=beₚ′=−bₚ and Kfₚ=Keₚ: for single matrix solution (37)

bfₚ′=[QSHₚ−(KfₚGₚₚ/Bₚₚ)PSHₚ]/(eₛ²+fₛ²)−bₚ: at PQ-node for two matrix solution (38)

beₚ′=−[QSHₚ−(KeₚGₚₚ/Bₚₚ)PSHₚ]/(eₛ²+f²)−bₚ: at PQ-node for two matrix solution (39)

bfₚ′=−Qₚ₀/Vₛ²−bₚ: at PV-node for two matrix solution (40)

beₚ′=Qₚ₀/Vₛ²−bₚ: at PV-node for two matrix solution (41)

(Qₚ₀—calculated at initial estimate solution, and factors Kfₚ and Keₚ are to be determined experimentally)

ΔRIₚ′=ΔRIₚ+(KfₚGₚₚ/Bₚₚ)ΔIIₚ: for PQ-nodes (42)

ΔIIₚ′=ΔIIₚ−(KeₚGₚₚ/Bₚₚ)ΔRIₚ: for PQ-nodes (43)

ΔPₚ′=ΔPₚ+(KfₚGₚₚ/Bₚₚ)ΔQₚ: for calculation of RRIₚ at PQ-nodes (44)

ΔQₚ′=ΔQₚ−(KfₚGₚₚ/Bₚₚ)ΔPₚ: for calculation of RRIₚ at PQ-nodes (45)

ΔPₚ′=ΔPₚ+(KfₚGₚₚ/Bₚₚ)ΔQₚ: for calculation of RIIₚ at PQ-nodes (46)

ΔQₚ′=ΔQₚ−(KfₚGₚₚ/Bₚₚ)ΔPₚ: for calculation of RIIₚ at PQ-nodes (47)

PSHₚ′=PSHₚ+(Gₚₚ/Bₚₚ)QSHₚ:for PQ-nodes (15)

QSHₚ′=QSHₚ−(Gₚₚ/Bₚₚ)PSHₚ: for PQ-nodes (16)

Kffₚ=|(Bₚₚ/Yfₚₚ)| (48)

Keeₚ=|(Bₚₚ/Yeₚₚ)| (49)

### Slack-Start

The same voltage magnitude and angle as those of the slack-node when used for all nodes as initial guess solution, provide Jacobian elements as determined in the appendix-A of “Super Super Decoupled Loadflow” Presented at IEEE Toronto International Conference—Science and Technology for Humanity (TIC-STH 2009), pp. 652-659, 26-27 Sep., 2009. With the specified magnitudes, PV-nodes voltage magnitudes are adjusted to their known values after the first half iteration. This start procedure referred to as the slack-start, saves almost all effort of mismatch calculation in the first P-f iteration as it requires only shunt flows to be calculated at each node.

where, Kₚ, Kffₚ, and Keeₚ are defined in equations (29), (48), and (49) respectively, which are initially restricted to the minimum value of 0.75 determined experimentally; however its restriction is lowered to the minimum value of 0.6 when its average over all less than 1.0 values at PV nodes is less than 0.6. Restrictions to the factors K's as stated in the above is system independent. Admittance magnitude in (15) is of the same algebraic sign as its susceptance. Equations (27) and (28) with inequality sign implies that nodal rotation angles are restricted to maximum of −36 to −90 degrees to be determined experimentally for CIPSDL models.

In super decoupled loadflow models [Yf] and [Ye] are real, sparse, symmetrical and built only from network elements. Since they are constant, they need to be factorized once only at the start of the solution. Equations (1) and (2) are to be solved repeatedly by forward and backward substitutions. [Yf] and [Ye] are of the same dimensions (m+k)×(m+k) when only a row/column of the reference/slack-node is excluded and both are triangularized using the same ordering regardless of the node-types.

Unlike the prior art SSDL methods, CIPSDL methods provide an opportunity for single matrix loadflow computations substantially reducing memory requirements, and since all nodes are active in the iterative process implementations of PQ-node to PV-node and PV-node to PQ-node switching is simple. The best possible convergence from non-linearity consideration could be achieved by restricting rotation angle to maximum of −36 to −90 degrees to be determined experimentally, and by experimentally determining corresponding factors Kfₚ and Keₚ.

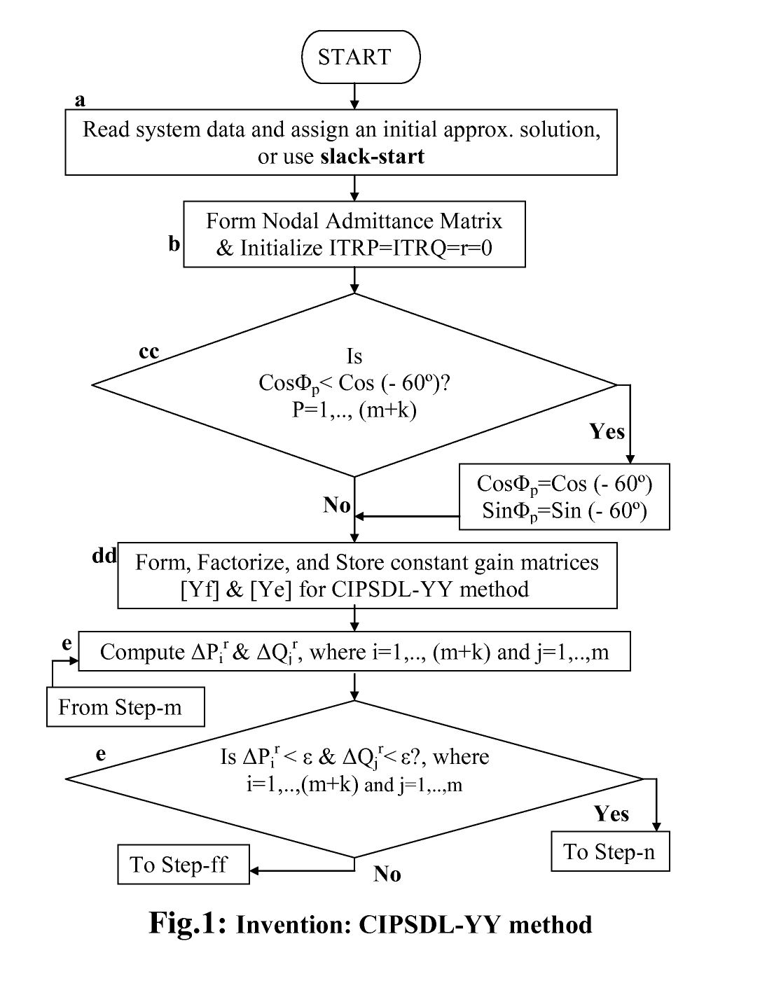

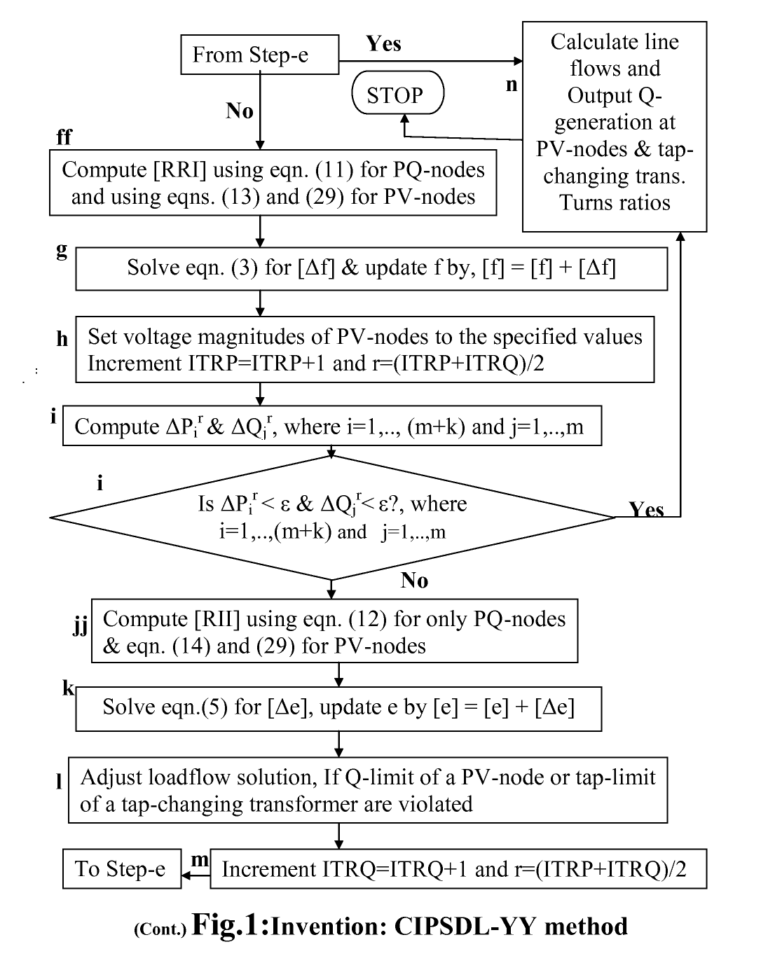

The steps of loadflow computation method, CIPSDL-YY method are shown in the flowchart of FIG. 1. Referring to the flowchart of FIG. 1, different steps are elaborated in steps marked with similar letters in the following. Double lettered steps are the characteristic steps of CIPSDL-YY method. The words “Read system data” in Step-a correspond to step-10 and step-20 in FIG. 5, and step-16, step-18, step-24, step-36, step-38 in FIG. 6. All other steps in the following correspond to step-30 in FIG. 5, and step-42, step-44, and step-46 in FIG. 6.
a. Read system data and assign an initial approximate solution. If better solution estimate is not available, set voltage magnitude and angle of all nodes equal to those of the slack-node. This is referred to as the slack-start.
b. Form nodal admittance matrix, and Initialize iteration count ITRF=ITRE=r=0
cc. Compute Cosine and Sine of nodal rotation angles using equations (27) and (28), and store them. If Cos Φₚ<Cos(−36° to −90°, to be determined experimentally), set Cos Φₚ=Cos(−36° to −90°) and Sin Φₚ=Sin (−36° to −90°).
dd. Form (m+k)×(m+k) size matrices [Yf] and [Ye] of (1) and (2) respectively each in a compact storage exploiting sparsity. The matrices are formed using equations (15), (16), (17). Factorize [Yf] and [Ye] using the same ordering of nodes regardless of node-types and store them using the same indexing and addressing information.
e. Compute residues [ΔP] at PQ- and PV-nodes and [ΔQ] at only PQ-nodes. If all are less than the tolerance (8), proceed to step-n. Otherwise follow the next step.
ff. Compute the vector of modified residues [RRI] as in (11) for PQ-nodes, and using (13) and (29) for PV-nodes.
g. Solve (3) for [Δf] and update imaginary component of voltage using, [f]=[f]+[Δf].
h. Set voltage magnitudes of PV-nodes equal to the specified values, and Increment the iteration count ITRF=ITRF+1 and r=(ITRF+ITRE)/2.
i. Compute residues [ΔP] at PQ- and PV-nodes and [ΔQ] at PQ-nodes only. If all are less than the tolerance (8), proceed to step-n. Otherwise follow the next step.
jj. Compute the vector of modified residues [RII] as in (12) for PQ-nodes, and using (14) and (29) for PV-nodes.
k. Solve (5) for [Δe] and update real component of voltage using [e]=[e]+[Δe].
l. Calculate reactive power generation at PV-nodes and tap positions of tap-changing transformers. If the maximum and minimum reactive power generation capability and transformer tap position limits are violated, implement the violated physical limits and adjust the loadflow solution by the method like one described in “LTC Transformers and MVAR violations in the Fast Decoupled Load Flow, IEEE Trans., PAS-101, No. 9, PP. 3328-3332, September 1982”.
m. Increment the iteration count ITRE=ITRE+1 and r=(ITRF+ITRE)/2, and Proceed to step-e.
n. From calculated values of voltage magnitude and voltage angle at PQ-nodes, voltage angle and reactive power generation at PV-nodes, and tap position of tap changing transformers, calculate power flows through power network components.

In super decoupled loadflow models [Yf] and [Ye] are real, sparse, symmetrical and built only from network elements. Since they are constant, they need to be factorized once only at the start of the solution. Equations (1) and (2) are to be solved repeatedly by forward and backward substitutions. [Yf] and [Ye] are of the same dimensions (m+k)×(m+k) when only a row/column of the reference/slack-node is excluded and both are triangularized using the same ordering regardless of the node-types.

Unlike the prior art SSDL methods, CIPSDL methods provide an opportunity for single matrix loadflow computations substantially reducing memory requirements, and since all nodes are active in the iterative process implementations of PQ-node to PV-node and PV-node to PQ-node switching is simple. The best possible convergence from non-linearity consideration could be achieved by restricting rotation angle to maximum of −36 to −90 degrees to be determined experimentally, and by experimentally determining corresponding factors Kf and Ke.

### New Gauss-Seidel-Patel Loadflow (NGSPL)

The complex conjugate power injected into the node-p of a power network is given by the following equation,

$${P}_{q} - {jQ}_{p} = {V}_{p}^{*} {\sum }_{q = 1}^{n} {Y}_{pq} {V}_{q} = {V}_{p}^{*} {Y}_{pp} {V}_{p} + {V}_{p}^{*} {\sum }_{q > p} {Y}_{pq} {V}_{q} \qquad ( 50 )$$

### Where,

$$\begin{matrix}{P}_{p} = Re \{ {V}_{p} * {\sum }_{q = 1}^{n} {Y}_{pq} {V}_{q} \} & ( 51 ) \\ {Q}_{p} = Im \{ {V}_{p} * {\sum }_{q = 1}^{n} {Y}_{pq} {V}_{q} \} & ( 52 )\end{matrix}$$

Where, Re means “real part of” and Im means “imaginary part of”. The equation (50) can also be written for complex power injected into the node-p, instead of complex conjugate power injected into the node-p for the purpose of the following development of a New Gauss-Seidel-Patel numerical and Loadflow method. However, detailed generalized propounding statement of the New Gauss-Seidel-Patel numerical method will be provided in the proposed book writing project.

The New Gauss-Seidel-Patel (NGSP) numerical method is for solving a set of simultaneous nonlinear algebraic equations iteratively. The NGSPL-method calculates complex node voltage from any node-p equation (50) as given in equation (53).

$${V}_{p} = ( {\sum }_{q > p} {Y}_{pq} {V}_{q} ) \text{/} [ \{ ( {PSH}_{p} - {jQSH}_{p} ) \text{/} ( {e}_{p}^{2} + {f}_{p}^{2} ) \} - {Y}_{pp} ] \qquad ( 53 )$$

### Iteration Process

Iterations start with the experienced/reasonable/logical guess for the solution. The reference node also referred to as the slack-node voltage being specified, starting voltage guess is made for the remaining (n−1)-nodes in n-node network. Node voltage value is immediately updated with its newly calculated value in the iteration process in which one node voltage is calculated at a time using latest updated other node voltage values. A node voltage value calculation at a time process is iterated over (n−1)-nodes in an n-node network, the reference node voltage being specified not required to be calculated.

Now, for the iteration-(r+1), the complex voltage calculation at node-p equation (53) and reactive power calculation at node-p equation (52), becomes

$$\begin{matrix}{V}_{p}^{( r + 1 )} = ( {\sum }_{q = 1}^{p - 1} {Y}_{pq} {V}_{q}^{( r + 1 )} + {\sum }_{q = p + 1}^{n} {Y}_{pq} {V}_{q}^{r} ) \text{/} [ \{ ( {PSH}_{p} - {jQSH}_{p} ) \text{/} {( {e}_{p}^{2} + {f}_{p}^{2} )}^{r} \} - {Y}_{pp} ] & ( 54 ) \\ {Q}_{p}^{( r + 1 )} = - Im \{ {( {V}_{p}^{*} )}^{r} {\sum }_{q = 1}^{p - 1} {Y}_{pq} {V}_{q}^{( r + 1 )} + {( {V}_{p}^{*} )}^{r} {\sum }_{q = p}^{n} {Y}_{pq} {V}_{q}^{r} \} & ( 55 )\end{matrix}$$

The well-known limitation of the Gauss-Seidel numerical method to be not able to converge to the high accuracy solution, was resolved in the Gauss-Seidel-Patel (GSP) numerical method by the introduction of the concept of self-iteration of each calculated variable until convergence before proceeding to calculate the next. This is achieved by replacing equation (54) by equation (56) stated in the following where self-iteration-(sr+1) over a node variable itself within the global iteration-(r+1) over (n−1) nodes in the n-node network is depicted. During the self-iteration process only Vₚ and its real and imaginary components change without affecting any of the terms involving V_{q}. At the start of the self-iteration Vₚ^{sr}=Vₚ^{r}, and at the convergence of the self-iteration Vₚ^{(r+1)}=Vₚ^{(sr+1)}.

$${( {V}_{p}^{( sr + 1 )} )}^{( r + 1 )} = ( {\sum }_{q = 1}^{p - 1} {Y}_{pq} {V}_{q}^{( r + 1 )} + {\sum }_{q = p + 1}^{n} {Y}_{pq} {V}_{q}^{r} ) \text{/} [ \{ ( {PSH}_{p} - {jQSH}_{p} ) \text{/} {( {( {e}_{p}^{2} + {f}_{p}^{2} )}^{sr} )}^{r} \} - {Y}_{pp} ] \qquad ( 56 )$$

### Self-Convergence

The self-iteration process for a node is carried out until changes in the real and imaginary parts of the node-p voltage calculated in two consecutive self-iterations are less than the specified tolerance. It has been possible to establish a relationship between the tolerance specification for self-convergence and the tolerance specification for global-convergence. It is found sufficient for the self-convergence tolerance specification to be ten times the global-convergence tolerance specification.

|Δfₚ^{(sr+1)}|=|fₚ^{(sr+1)}fₚ^{sr}|<10ε (57)

|Δeₚ^{(sr+1)}|=|eₚ^{(sr+1)}−eₚ^{sr}|<10ε (58)

For the global-convergence tolerance specification of 0.000001, it has been found sufficient to have the self-convergence tolerance specification of 0.00001 in order to have the maximum real and reactive power mismatches of 0.0001 in the converged solution. However, for small networks under not difficult to solve conditions they respectively could be 0.00001 and 0.0001 or 0.000001 and 0.0001, and for large networks under difficult to solve conditions they sometimes need to be respectively 0.0000001 and 0.000001.

### Convergence

The iteration process is carried out until changes in the real and imaginary parts of the set of (n−1)-node voltages calculated in two consecutive iterations are all less than the specified tolerance—ε, as shown in equations (59) and (60). The lower the value of the specified tolerance for convergence check, the greater the solution accuracy.

|Δfₚ^{(r+1)}|=|fₚ^{(r+1)}−fₚ^{r}|<ε (59)

|Δeₚ^{(r+1)}|=|eₚ^{(r+1)}−eₚ^{r}|<ε (60)

### Accelerated Convergence

The GSP-method being inherently slow to converge, it is characterized by the use of an acceleration factor applied to the difference in calculated node voltage between two consecutive iterations to speed-up the iterative solution process. The accelerated value of node-p voltage at iteration-(r+1) is given by

Vₚ^{(r+1)}(accelerated)=Vₚ^{r}+β(Vₚ^{(r+1)}−Vₚ^{r}) (61)

Where, β is the real number called acceleration factor, the value of which for the best possible convergence for any given network can be determined by trial solutions. The GSP-method is very sensitive to the choice of β, causing very slow convergence and even divergence for the wrong choice.

### Scheduled or Specified Voltage at a PV-Node

Of the four variables, real power PSHₚ and voltage magnitude VSHₚ are scheduled/specified/set at a PV-node. If the reactive power calculated using VSHₚ at the PV-node is within the upper and lower generation capability limits of a PV-node generator, it is capable of holding the specified voltage at its terminal. Therefore the complex voltage calculated by equation (54) or (56) by using actually calculated reactive power Qₚ in place of QSHₚ is adjusted to specified voltage magnitude by equation (62). However, in case of violation of upper or lower generation capability limits of a PV-node generator, a violated limit value is used for QSHₚ in (54) and (56), meaning a PV-node generator is no longer capable of holding its terminal voltage at its scheduled voltage VSHₚ, and the PV-node is switched to a PQ-node type.

Vₚ^{(r+1)}=(VSHₚVₚ^{(r+1)})/|Vₚ^{(r+1)}| (62)

### Calculation Steps of New Gauss-Seidel-Patel Loadflow (NGSPL) Method

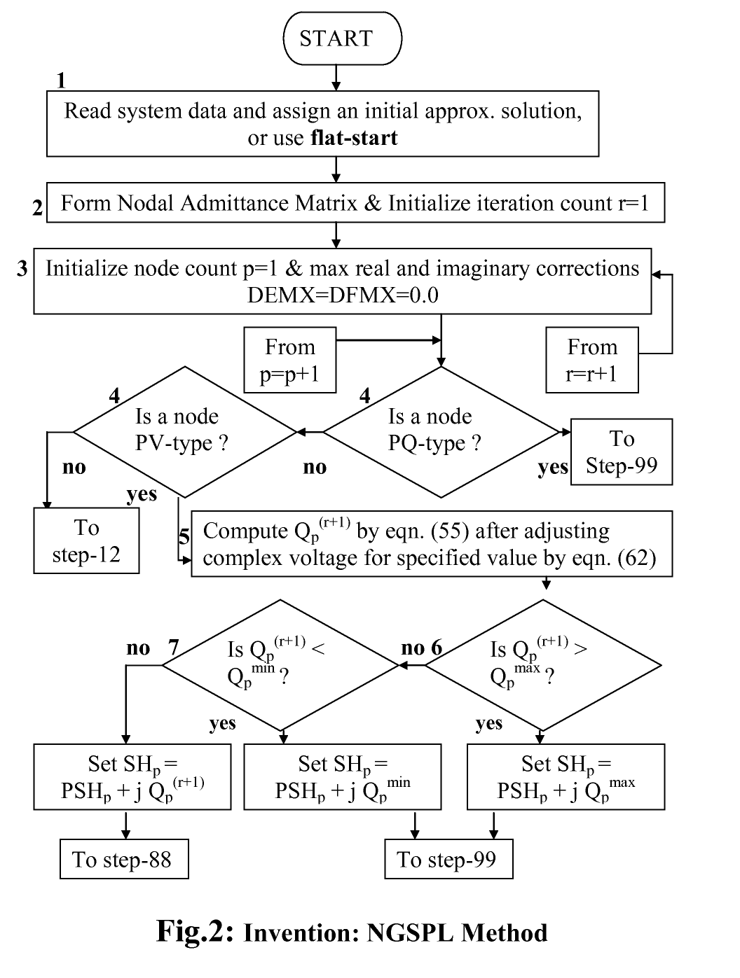

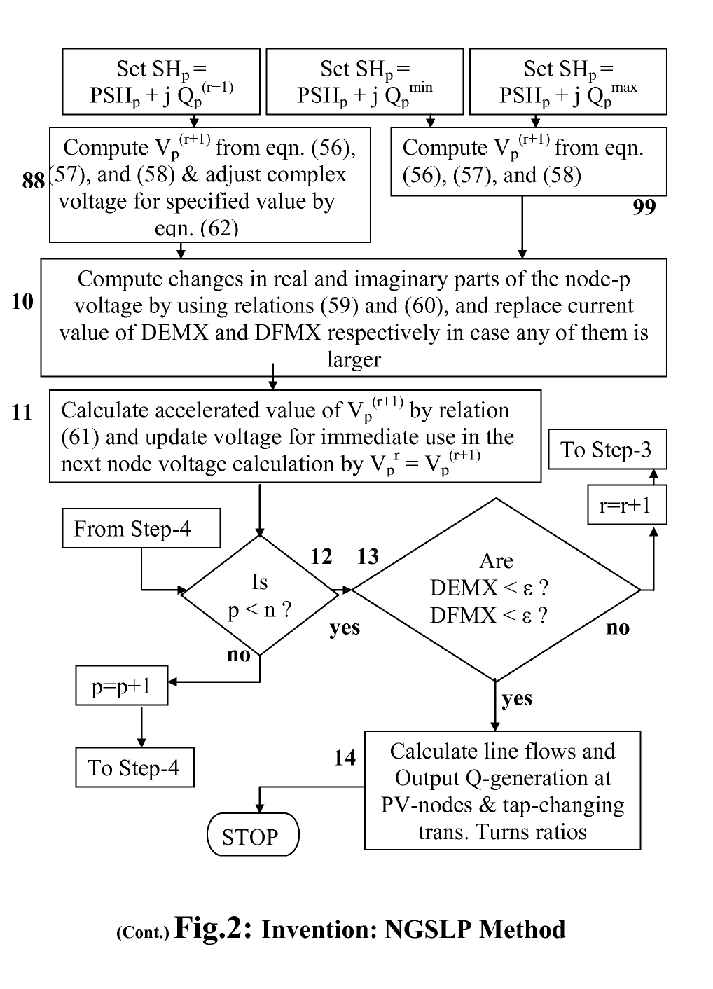

The steps of loadflow calculation by NGSPL method are shown in the flowchart of FIG. 2. Referring to the flowchart of FIG. 2, different steps are elaborated in steps marked with similar numbers in the following. Steps marked with double numerals are the inventive steps. The words The words “Read system data” in Step-a correspond to step-10 and step-20 in FIG. 5, and step-16, step-18, step-24, step-36, step-38 in FIG. 6. All other steps in the following correspond to step-30 in FIG. 5, and step-42, step-44, and step-46 in FIG. 6.
1. Read system data and assign an initial approximate solution. If better solution estimate is not available, set specified voltage magnitude at PV-nodes, 1.0 p.u. voltage magnitude at PQ-nodes, and all the node angles equal to that of the slack-node angle, which is referred to as the flat-start.
2. Form nodal admittance matrix, and Initialize iteration count r=1
3. Scan all the node of a network, except the slack-node whose voltage having been specified need not be calculated. Initialize node count p=1, and initialize maximum change in real and imaginary parts of node voltage variables DEMX=0.0 and DFMX=0.0
4. Test for the type of a node at a time. For the slack-node go to step-12, for a PQ-node go to the step-99, and for a PV-node follow the next step.
5. Compute Qₚ^{(r+1)} for use as an imaginary part in determining complex schedule power at a PV-node from equation (55) after adjusting its complex voltage for specified value by equation (62)
6. If Qₚ^{(r+1)} is greater than the upper reactive power generation capability limit of the PV-node generator, set QSHₚ=the upper limit Qₚ^{max} for use in equation (56), and go to step-99. If not, follow the next step.
7. If Qₚ^{(r+1)} is less than the lower reactive power generation capability limit of the PV-node generator, set QSHₚ=the lower limit Qₚ^{min} for use in equation (56), and go to step-99. If not, follow the next step.
88. Compute Vₚ^{(r+1)} by equations (56), (57), (58) involving self-iteration using QSHₚ=Qₚ^{(r+1)}, and adjust for specified voltage at the PV-node by equation (62), and go to step-10.
99. Compute Vₚ^{(r+1)} by equations (56), (57), (58) involving self iteration
10. Compute changes in the imaginary and real parts of the node-p voltage by using equations (59) and (60), and replace current value of DFMX and DEMX respectively in case any of them is larger.
11. Calculate accelerated value of Vₚ^{(r+1)} by using equation (61), and update voltage by Vₚ^{r}=Vₚ^{(r+1)} for immediate use in the next node voltage calculation.
12. Check for if the total numbers of nodes—n are scanned. That is if p<n, increment p=p+1, and go to step-4. Otherwise follow the next step.
13. If DEMX and DFMX both are not less than the convergence tolerance (E) specified for the purpose of the accuracy of the solution, advance iteration count r=r+1 and go to step-3, otherwise follow the next step
14. From calculated and known values of complex voltage at different power network nodes, and tap position of tap changing transformers, calculate power flows through power network components, and reactive power generation at PV-nodes.

### Decoupled Gauss-Seidel-Patel Loadflow Methods

Real and imaginary components of current injection at node-p are given as:

$$\begin{matrix}{RI}_{p} = ( {e}_{p} {P}_{p} + {f}_{p} {Q}_{p} ) / ( {e}_{p}^{2} + {f}_{p}^{2} ) = - [ ( {B}_{pp} + {b}_{p} ) {f}_{p} + {\sum }_{q > p} {B}_{pq} {f}_{q} ] + [ ( {G}_{pp} + {g}_{p} ) {e}_{p} - {\sum }_{q > p} {G}_{pq} {e}_{q} ] & ( 63 ) \\ {II}_{p} = ( {e}_{p} {Q}_{p} - {f}_{p} {P}_{p} ) / ( {e}_{p}^{2} + {f}_{p}^{2} ) = - [ ( {G}_{pp} + {g}_{p} ) {f}_{p} + {\sum }_{q > p} {G}_{pq} {f}_{q} ] - [ ( {B}_{pp} + {b}_{p} ) {e}_{p} - {\sum }_{q > p} {B}_{pq} {e}_{q} ] & ( 64 )\end{matrix}$$

Rearranging equations (63) and (64) in two different ways provides two different Decoupled Gauss-Seidel-Patel Loadflow methods DGSPL1 comprising (65) and (66), or (67) and (68), and DGSPL2 comprising equations (69) and (70), or (71) and (72),

$$\begin{matrix}{f}_{p} = [ ( {e}_{p} {P}_{p} + {f}_{p} {Q}_{p} ) \text{/} ( {e}_{p}^{2} + {f}_{p}^{2} ) - \{ ( {G}_{pp} + {g}_{p} ) {e}_{p} - {\sum }_{q > p} {G}_{pq} {e}_{q} \} + {\sum }_{q > p} {B}_{pq} {f}_{q} ] \text{/} - ( {B}_{pp} + {b}_{p} ) & ( 65 ) \\ {e}_{p} = [ ( {e}_{p} {Q}_{p} - {f}_{p} {P}_{p} ) \text{/} ( {e}_{p}^{2} + {f}_{p}^{2} ) + \{ ( {G}_{pp} + {g}_{p} ) {f}_{p} + {\sum }_{q > p} {G}_{pq} {f}_{q} \} - {\sum }_{q > p} {B}_{pq} {e}_{q} ] \text{/} - ( {B}_{pp} + {b}_{q} ) & ( 66 ) \\ {( {f}_{p}^{( sr + 1 )} )}^{( r + 1 )} = [ ( {e}_{p} {P}_{p} + {( {f}_{p}^{sr} )}^{r} {Q}_{p} ) / {( {e}_{p}^{2} + {( {f}_{p}^{2} )}^{sr} )}^{r} - \{ ( {G}_{pp} + {g}_{p} ) {e}_{p} - {\sum }_{q > p} {G}_{pq} {e}_{q} \} + {\sum }_{q > p} {B}_{pq} {f}_{q}^{( r + 1 )} + {\sum }_{q > p} {B}_{pq} {f}_{q}^{r} ] \text{/} - ( {B}_{pp} + {b}_{p} ) & ( 67 ) \\ {( {e}_{p}^{( sr + 1 )} )}^{( r + 1 )} = [ ( {( {e}_{p}^{sr} )}^{r} {Q}_{p} - {f}_{p} {P}_{p} ) \text{/} {( {( {e}_{p}^{2} )}^{sr} )}^{r} + {f}_{p}^{2} ) + \{ ( {G}_{pp} + {g}_{p} ) {f}_{p} + {\sum }_{q > p} {G}_{pq} {f}_{q} \} - {\sum }_{q > p} {B}_{pq} {e}_{q}^{( r + 1 )} - {\sum }_{q > p} {B}_{pq} {e}_{q}^{r} ] \text{/} - ( {B}_{pp} + {b}_{p} ) & ( 68 ) \\ {f}_{p} = [ ( {e}_{p} {P}_{p} ) \text{/} ( {e}_{p}^{2} + {f}_{p}^{2} ) - \{ ( {G}_{pp} + {g}_{p} ) {e}_{p} - {\sum }_{q > p} {G}_{pq} {e}_{q} \} + {\sum }_{q > p} {B}_{pq} {f}_{q} ] \text{/} [ - {Q}_{p} / ( {e}_{p}^{2} + {f}_{p}^{2} ) - ( {B}_{pp} + {b}_{p} ) ] & ( 69 ) \\ {e}_{p} = [ ( - {f}_{p} {P}_{p} ) \text{/} ( {e}_{p}^{2} + {f}_{p}^{2} ) + \{ ( {G}_{pp} + {g}_{p} ) {f}_{p} + {\sum }_{q > p} {G}_{pq} {f}_{q} \} - {\sum }_{q > p} {B}_{pq} {e}_{q} ] \text{/} [ - {Q}_{p} / ( {e}_{p}^{2} + {f}_{p}^{2} ) - ( {B}_{pp} + {b}_{p} ) ] & ( 70 ) \\ {( {f}_{p}^{( sr + 1 )} )}^{( r + 1 )} = [ ( {e}_{p} {P}_{p} ) \text{/} {( {e}_{p}^{2} + {( {f}_{p}^{2} )}^{sr} )}^{r} - \{ ( {G}_{pp} + {g}_{p} ) {e}_{p} - {\sum }_{q > p} {G}_{pq} {e}_{q} \} + {\sum }_{q > p} {B}_{pq} {f}_{q}^{( r + 1 )} + {\sum }_{q > p} {B}_{pq} {f}_{q}^{r} ] \text{/} [ - {Q}_{p} \text{/} {( {e}_{p}^{2} + {( {f}_{p}^{2} )}^{sr} )}^{r} ) - ( {B}_{pp} + {b}_{p} ) ] & ( 71 ) \\ {( {e}_{p}^{( sr + 1} )}^{( r + 1 )} = [ ( - {f}_{p} {P}_{p} ) \text{/} {( {( {e}_{p}^{2} )}^{sr} )}^{r} + {f}_{p}^{2} ) + \{ ( {G}_{pp} + {g}_{p} ) {g}_{p} + {\sum }_{q > p} {G}_{pq} {f}_{q} \} - {\sum }_{q > p} {B}_{pq} {e}_{q}^{( r + 1 )} - {\sum }_{q > p} {B}_{pq} {e}_{q}^{r} ] \text{/} [ - {Q}_{p} / {( {( {e}_{p}^{2} )}^{sr} )}^{r} + {f}_{p}^{2} ) - ( {B}_{pp} + {b}_{p} ) ] & ( 72 )\end{matrix}$$

### Calculation Steps of Decoupled Gauss-Seidel-Patel Loadflow (DGSPL) Method

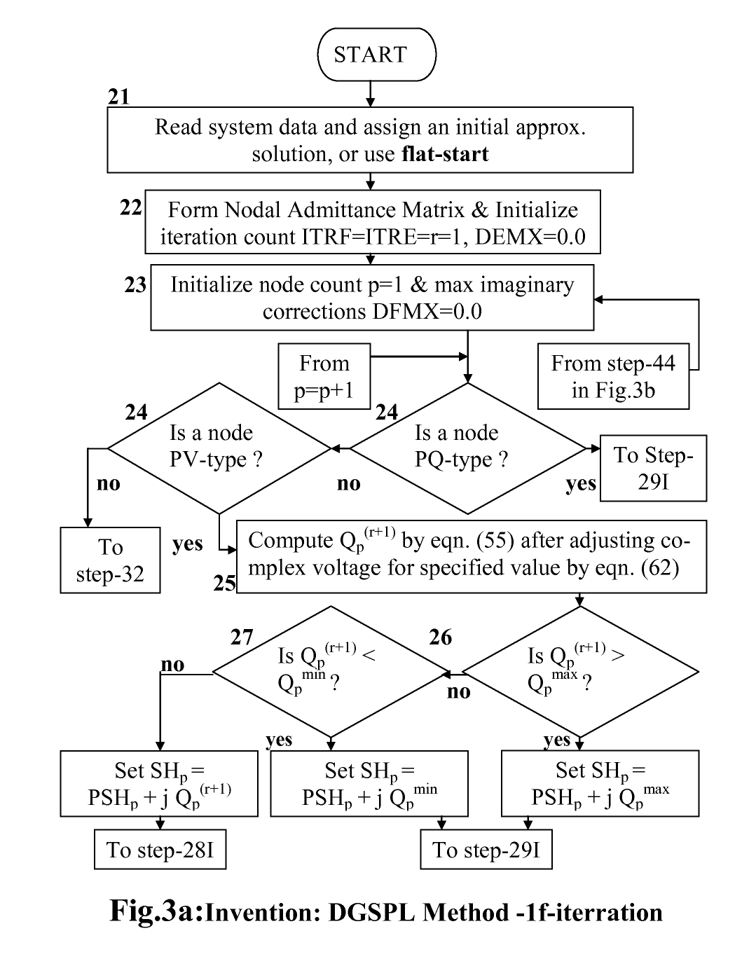

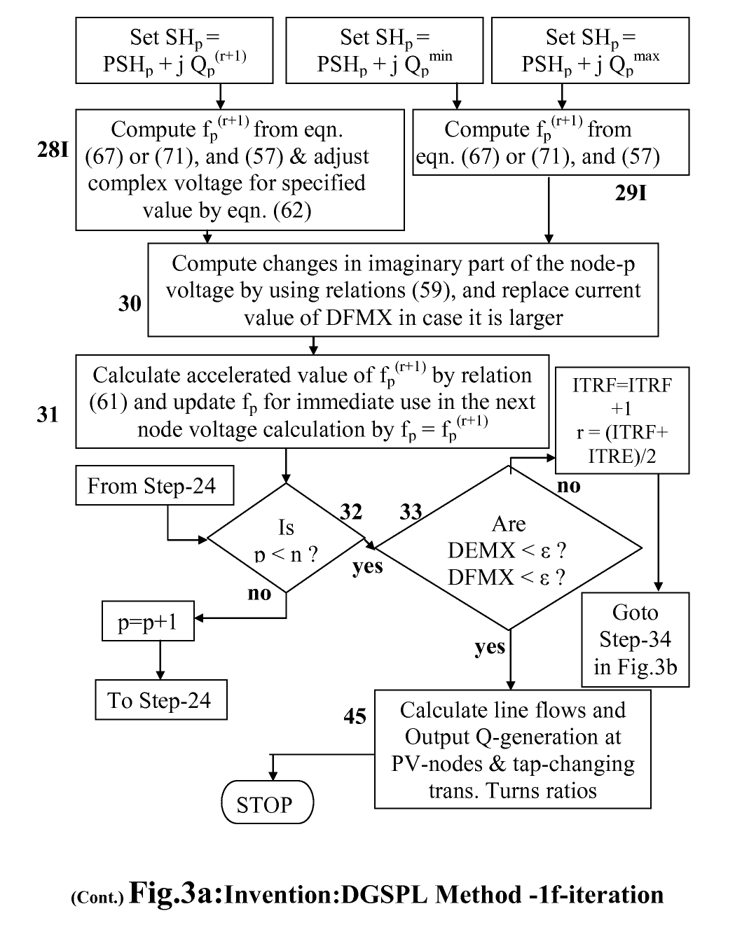

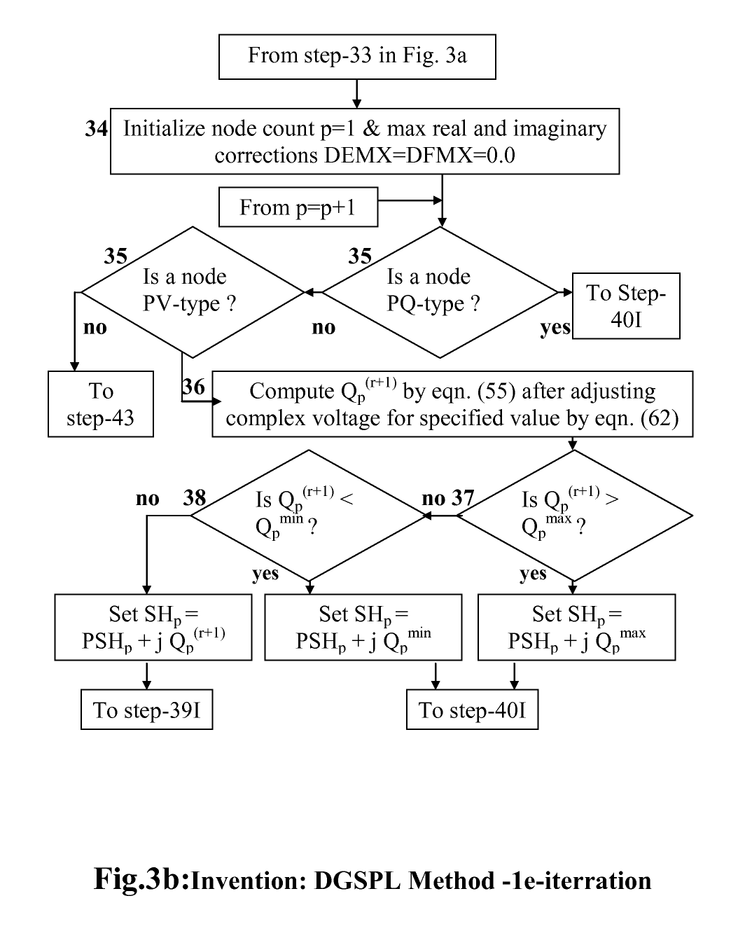

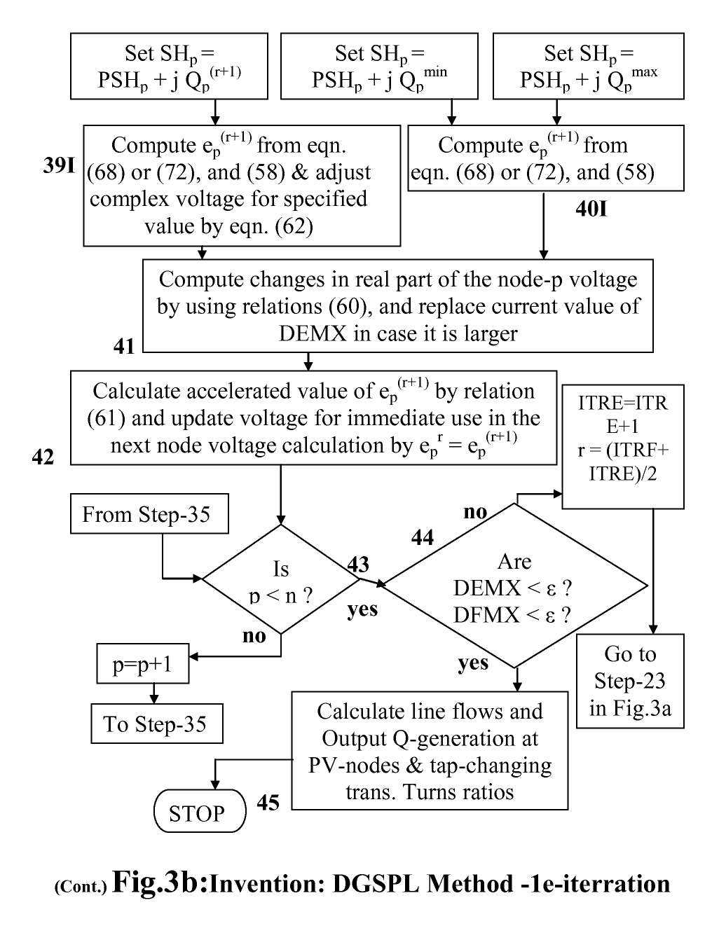

The steps of loadflow calculation by DGSPL method are shown in the flowchart of FIG. 3a and FIG. 3b. Referring to the flowchart of FIG. 3a and FIG. 3b, different steps are elaborated in steps marked with similar numbers in the following. Steps numbers containing letter “I” are the inventive steps. It should be noted that the flowchart of FIG. 3a and FIG. 3b and corresponding steps in the following are for (1f, 1e) iteration scheme, and there are other iteration schemes possible. The words “Read system data” in Step-1 correspond to step-10 and step-20 in FIG. 5, and step-16, step-18, step-24, step-36, step-38 in FIG. 6. All other steps in the following correspond to step-30 in FIG. 5, and step-42, step-44, and step-46 in FIG. 6.
21. Read system data and assign an initial approximate solution. If better solution estimate is not available, set specified voltage magnitude at PV-nodes, 1.0 p.u. voltage magnitude at PQ-nodes, and all the node angles equal to that of the slack-node angle, which is referred to as the flat-start.
22. Form nodal admittance matrix, and Initialize iteration count ITRF=ITRE=r=1, DEMX=0.0
23. Scan all the nodes of a network, except the slack-node whose voltage having been specified need not be calculated. Initialize node count p=1, and initialize maximum change in imaginary part of node voltage variable DFMX=0.0
24. Test for the type of a node at a time. For the slack-node go to step-32, for a PQ-node go to the step-29I, and for a PV-node follow the next step.
25. Compute Qₚ^{(r+1)} for use as an imaginary part in determining complex schedule power at a PV-node from equation (55) after adjusting its complex voltage for specified value by equation (62).
26. If Qₚ^{(r+1)} is greater than the upper reactive power generation capability limit of the PV-node generator, set QSHₚ=the upper limit Qₚ^{max} for use in equation (67) or (71), and go to step-29I. If not, follow the next step.
27. If Qₚ^{(r+1)} is less than the lower reactive power generation capability limit of the PV-node generator, set QSHₚ=the lower limit Qₚ^{min} for use in equation (67) or (71), and go to step-29I. If not, follow the next step.
281. Compute fₚ^{(r+1)} by equations (67) or (71), and (57) involving self-iteration using QSHₚ=Qₚ^{(r+1)}, and adjust its value for specified voltage at the PV-node by equation (62), and go to step-30.
29I. Compute fₚ^{(r+1)} by equations (67) or (71), and (57) involving self iteration
30. Compute change in the imaginary part of the node-p voltage by using equations (59), and replace current value of DFMX in case it is larger.
31. Calculate accelerated value of fₚ^{(r+1)} by using equation (61), and update voltage by fₚ^{r}=fₚ^{(r+1)} for immediate use in the next node voltage calculation.
32. Check for if the total numbers of nodes—n are scanned. That is if p<n, increment p=p+1, and go to step-24. Otherwise follow the next step.
33. If DEMX and DFMX both are not less than the convergence tolerance (E) specified for the purpose of the accuracy of the solution, advance iteration count ITRF=ITRF+1, and r=(ITRF+ITRE)/2 and follow the next step, otherwise go to step-45.
34. Scan all the node of a network, except the slack-node whose voltage having been specified need not be calculated. Initialize node count p=1, and initialize maximum change in real part of node voltage variable DEMX=0.0.
35. Test for the type of a node at a time. For the slack-node go to step-43, for a PQ-node go to the step-40I, and for a PV-node follow the next step.
36. Compute Qₚ^{(r+1)} for use as an imaginary part in determining complex schedule power at a PV-node from equation (55) after adjusting its complex voltage for specified value by equation (62).
37. If Qₚ^{(r+1)} is greater than the upper reactive power generation capability limit of the PV-node generator, set QSHₚ=the upper limit Qₚ^{max} for use in equation (68) or (72), and go to step-40I. If not, follow the next step.
38. If Qₚ^{(r+1)} is less than the lower reactive power generation capability limit of the PV-node generator, set QSHₚ=the lower limit Qₚ^{min} for use in equation (68) or (72), and go to step-40I. If not, follow the next step.
39I. Compute eₚ^{(r+1)} by equations (68) or (72), and (58) involving self-iteration using QSHₚ=Qₚ^{(r+1)}, and adjust its value for specified voltage at the PV-node by equation (62), and go to step-41.
40I. Compute eₚ^{(r+1)} by equations (68) or (72), and (58) involving self iteration
41. Compute change in the real part of the node-p voltage by using equation (60), and replace current value of DEMX in case it is larger.
42. Calculate accelerated value of eₚ^{(r+1)} by using equation (61), and update voltage by eₚ^{r}=eₚ^{(r+1)} for immediate use in the next node voltage calculation.
43. Check for if the total numbers of nodes—n are scanned. That is if p<n, increment p=p+1, and go to step-35. Otherwise follow the next step.
44. If DEMX and DFMX both are not less than the convergence tolerance (E) specified for the purpose of the accuracy of the solution, advance iteration count ITRE=ITRE+1, and r=(ITRF+ITRE)/2 and go to step-23, otherwise follow the next step.
45. From calculated and known values of complex voltage at different power network nodes, and tap position of tap changing transformers, calculate power flows through power network components, and reactive power generation at PV-nodes.

### Complex Newton-Raphson-Patel Loadflow (CNRPL) Using Complex Algebra

The model CNRPL comprises equations (73) to (76) and/or (77) to (80).

[ΔI]=[J][ΔV] (73)

### Where,

$$\begin{matrix}Δ {I}_{p} = [ \{ ( {PSH}_{p} - {jQSH}_{p} ) / ( {e}_{p}^{2} + {f}_{p}^{2} ) \} - {Y}_{pp} ] {V}_{p} - {\sum }_{q > p} {Y}_{pq} {V}_{q} ) & ( 74 ) \\ {J}_{pq} = {Y}_{pq} & ( 75 ) \\ {J}_{pp} = [ \{ - ( {PSH}_{p} - {jQSH}_{p} ) / ( {e}_{p}^{2} + {f}_{p}^{2} ) \} + {Y}_{pp} ] & ( 76 ) \\ [ Δ {I}^{*} ] = [ {J}^{*} ] [ Δ {V}^{*} ] & ( 77 )\end{matrix}$$

### Where,

$$\begin{matrix}Δ {I}_{p}^{*} = [ \{ ( {PSH}_{p} - {jQSH}_{p} ) / ( {e}_{p}^{2} + {f}_{p}^{2} ) \} - {Y}_{pp}^{*} ] {V}_{p}^{*} - {\sum }_{q > p} {Y}_{pq}^{*} {V}_{q}^{*} ) & ( 78 ) \\ {J}_{pq}^{*} = {Y}_{pq}^{*} & ( 79 ) \\ {J}_{pp}^{*} = [ \{ - ( {PSH}_{p} - {jQSH}_{p} ) / ( {e}_{p}^{2} + {f}_{p}^{2} ) \} + {Y}_{pp}^{*} ] & ( 80 )\end{matrix}$$

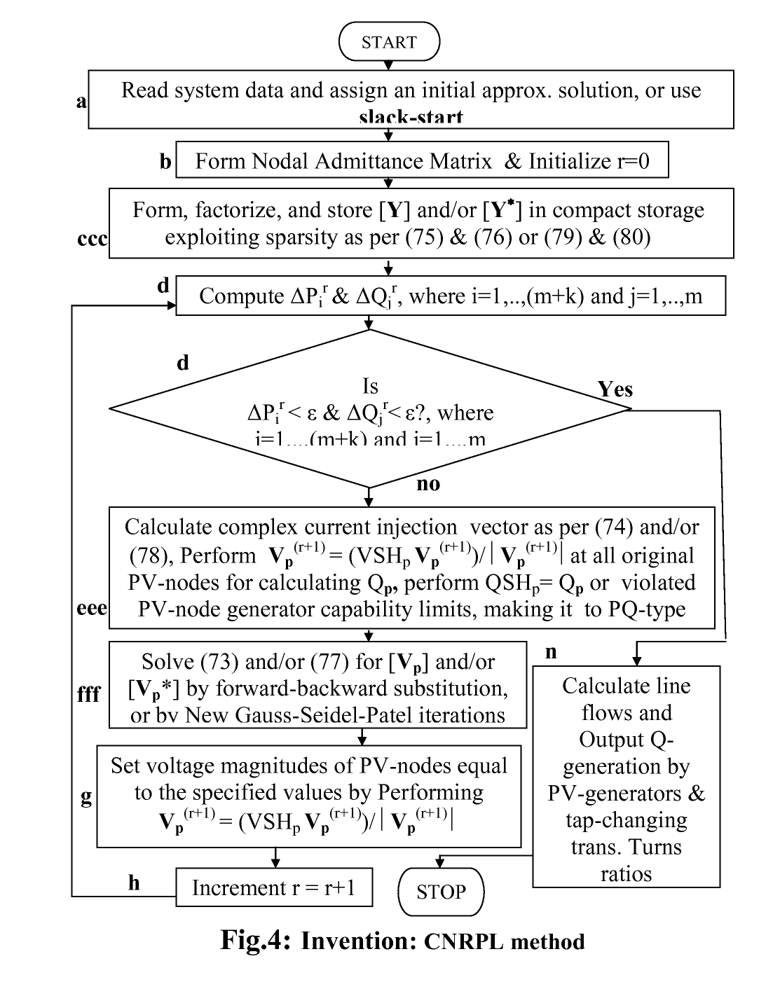

The steps of loadflow calculation by CNRPL method are shown in the flowchart of FIG. 4. Referring to the flowchart of FIG. 4, different steps are elaborated in steps marked with similar numbers in the following. Triple lettered steps are the inventive steps. The words “Read system data” in Step-a correspond to step-10 and step-20 in FIG. 5, and step-16, step-18, step-24, step-36, step-38 in FIG. 6. All other steps in the following correspond to step-30 in FIG. 5, and step-42, step-44, and step-46 in FIG. 6.
a. Read system data and assign an initial approximate solution. If better solution estimate is not available, set voltage magnitude and angle of all nodes equal to those of the slack-node. This is referred to as the slack-start.
b. Form nodal admittance matrix, and Initialize iteration count r=0
ccc. Form (m+k)×(m+k) size complex matrices [J] and/or [J*] of (73) and (77) respectively each in a compact storage exploiting sparsity. The complex matrices are formed using equations (75) and (76), and/or (79) and (80). Factorize [J] and/or [J*] using the same ordering of nodes regardless of node-types and store them using the same indexing and addressing information.
d. Compute residues [ΔP] at PQ- and PV-nodes and [ΔQ] at only PQ-nodes. If all are less than the tolerance (8), proceed to step-n. Otherwise follow the next step.
eee. Compute the vector of complex current injection vectors using equations (74) and/or (78). The value of QSHₚ at PV-nodes is calculated with the latest available [V] and/or [V*], and violated reactive power generation capability limit of generator of a PV-node is implemented by setting the value of QSHₚ equal to the violated limit.
ggg. Solve (73) and/or (77) for [ΔV] and/or [ΔV*] and update voltage using, [V]=[V]+[ΔV], and/or [V*]=[V*]+[ΔV*].
h. Set voltage magnitudes of PV-nodes equal to the specified values by adjusting as per equation (62), and Increment the iteration count r=r+1.
n. From calculated values of complex voltage, voltage angle and reactive power generation at PV-nodes, and tap position of tap changing transformers, calculate power flows through power network components.

The following inventions are based on Patel Numerical Method propounded by this inventor in 2007. The invented class of methods of forming/defining and solving loadflow computation models of a power network are the methods that organize a set of nonlinear algebraic equations in linear form as a product of coefficient matrix and unknown vector on one side of the matrix equation and all the other terms on the other side as known vector, and then solving the linear matrix equation for unknown vector in an iterative fashion.

### Patel Loadflow (PL) Model

Equations (63) and (64) can be organized in matrix form as per Patel Numerical Method:

$$( \begin{matrix}IR \\ II\end{matrix} ) = ( \begin{matrix}- B & G \\ - G & - B\end{matrix} ) ( \begin{matrix}f \\ e\end{matrix} ) \qquad ( 81 )$$

### Patel Transformation Decoupled Loadflow Model

[IR′]=[−Y][f] (82)

[II′]=[−Y][e] (83)

where,

IRₚ′=(eₚPSHₚ′+fₚQSHₚ′)/(eₚ²+fₚ²) (84)

IIₚ′=(eₚQSHₚ′−fₚPSHₚ′)/(eₚ²+fₚ²) (85)

This is the model where elements of equations (82) and 83) are defined by following equations.

[−Y]=[−B]+[G][−B]⁻¹[G] (86)

[IR′]=[IR]−[G][−B]⁻¹[II] (87)

[II′]=[II]+[G][−B]⁻¹[RI] (88)

Regular loadflow models can also be obtained by differentiating on both sides of equations (81), (82) and (83).

### Generalized Gauss-Seidel-Patel Numerical Method for Solution of System of Simultaneous Algebraic Equations Both Linear and Nonlinear:

A linear system of equations Ax=b can be written for any equation-p as equations (89) and (90):

$$\begin{matrix} {x}_{p}^{( r + 1 )} = ( {\sum }_{q = 1}^{p - 1} {a}_{pq} {x}_{q}^{( r + 1 )} + {\sum }_{q = p + 1}^{n} {a}_{pq} {x}_{q}^{r} ) \text{/} [ \{ {b}_{p} \text{/} {( {x}_{p} )}^{r} \} - {a}_{pp} ] & ( 89 ) \\ {( {x}_{p}^{( sr + 1 )} )}^{( r + 1 )} = ( {\sum }_{q = 1}^{p - 1} {a}_{pq} {x}_{q}^{( r + 1 )} - {\sum }_{q = p + 1}^{n} {a}_{pq} {x}_{q}^{r} ) \text{/} [ \{ {b}_{p} \text{/} {( {( {x}_{p} )}^{sr} )}^{r} \} - {a}_{pp} ] & ( 90 )\end{matrix}$$

A nonlinear system of equations f(x)=y can be written for any equation-p as equations (56), which is specifically a nonlinear power flow equation of a power network involving complex variables and constant parameters.

Equations (90) and (56) are defining equations of Generalized Gauss-Seidel-Patel numerical method involving self iterations. It should be noted that self-iterations within global iterations are analogous to the earth rotating on its own axis while making rounds around the Sun. This generalized approach for solution of both linear and nonlinear system of simultaneous algebraic equations could potentially be amenable to acceleration factors greater than 2 unlike original Gauss-Seidel numerical method subject to experimental numerical verification. Further verbal elaborations about the Generalized Gauss-Seidel-Patel numerical method will be provided as part of the proposed book writing project.

### General Statements

The system stores a representation of the reactive capability characteristic of each machine and these characteristics act as constraints on the reactive power, which can be calculated for each machine.

While the description above refers to particular embodiments of the present invention, it will be understood that many modifications may be made without departing from the spirit thereof. The accompanying claims are intended to cover such modifications as would fall within the true scope and spirit of the present invention.

The presently disclosed embodiments are therefore to be considered in all respect as illustrative and not restrictive, the scope of the invention being indicated by the appended claims in addition to the foregoing description, and all changes which come within the meaning and range of equivalency of the claims are therefore intended to be embraced therein.

The embodiments of the invention in which an exclusive property or privilege is claimed are defined as follows:

1. Methods of forming and solving invented Loadflow computation models of a power network to affect control of voltages and power flows in a power system, comprising the steps of:
obtaining on-line or simulated data of open or close status of all switches and circuit breakers in the power network, and reading data of operating limits of components of the power network including maximum Voltage×Ampere (VA or MVA) carrying capability limits of transmission lines, transformers, and PV-node, a generator-node where Real-Power-P and Voltage-Magnitude-V are specified, maximum and minimum reactive power generation capability limits of generators, and transformers tap position limits,
obtaining on-line readings of specified Real-Power-P and Reactive-Power-Q at PQ-nodes, Real-Power-P and voltage-magnitude-V at PV-nodes, voltage magnitude and angle at a slack node, and transformer turns ratios, wherein said on-line readings are the controlled variables,
performing loadflow computation by solving one of the invented CIPSDL-YY, CIPSDL-XX, NGSPL, DGSPL, CNRPL PL, PTDL computation model to calculate, complex voltages or their real and imaginary components or voltage magnitude and voltage angle at nodes of the power network providing for calculation of power flow through different components of the power network, and to calculate reactive power generations at PV-nodes and slack node, real power generation at the slack node and transformer tap-position indications,
evaluating loadflow computation for any over loaded components of the power network and for under or over voltage at any of the nodes of the power network,
correcting one or more controlled variables and repeating the performing loadflow computation, evaluating, and correcting steps until evaluating step finds no over loaded components and no under or over voltages in the power network, and
affecting a change in power flow through components of the power network and voltage magnitudes and angles at the nodes of the power network by actually implementing the finally obtained values of controlled variables after evaluating step finds a good power system or stated alternatively the power network without any overloaded components and under or over voltages, which finally obtained controlled variables however are stored for acting upon fast in case a simulated event actually occurs.
